(19) United States
(12) Patent Application Publication
(10) Pub. No.: US 2025/0005416 A1
(43) Pub. Date: Jan. 2, 2025

(54) QUANTUM DEVICE

(71) Applicant: NEC Corporation, Minato-ku, Tokyo (JP)

(72) Inventors: Akira MIYATA, Tokyo (JP); Tomohiro Yamaji, Toyko (JP)

(73) Assignee: NEC Corporation, Minato-ku, Tokyo (JP)

(21) Appl. No.: 18/581,496

(22) Filed: Feb. 20, 2024

(30) Foreign Application Priority Data
Feb. 24, 2023 (JP) 2023*027606

(51) Int. Cl. G06N 10/40; H05K 1/11; H10N 60/12; H10N 60/81; H10N 69/00

(52) U.S. Cl. CPC G06N 10/40; H05K 1/11; H10N 60/12; H10N 60/815; H10N 69/00

(57) ABSTRACT

A quantum device includes a first unit region with a first coupler, a first qubit, a second coupler, and a second qubit located on first to fourth vertices in this order, and a second unit region with the first coupler, the second qubit, a third coupler and a third qubit located on first to fourth vertices in this order, the first and fourth vertices of the first unit region being the first and second vertices of the second unit region. The first unit region includes a capacitive coupling port of the second coupler, and an inductive coupling port of the second qubit, in vicinities of the second coupler and the second qubit. The second unit region includes a capacitive coupling port of the second qubit, and an inductive coupling port of the third coupler in vicinities of the second qubit and the third coupler.

### FIELD

### Cross Reference to Related Applications

This application is based upon and claims the benefit of the priority of Japanese patent application No. 2023-027606, filed on Feb. 24, 2023, the disclosure of which is incorporated herein in its entirety by reference thereto.

The present invention relates to a quantum device provided with a superconducting circuit.

### BACKGROUND

A quantum bit (qubit) including a superconducting quantum circuit, is typically configured as a planar circuit formed by e.g., deposition of a superconducting material on a high resistance semiconductor substrate, and a non-linear inductor such as a Josephson junction and a superconducting quantum interference device (SQUID) including multiple Josephson junctions.

A coupling of qubits (such as two-body and four-body coupling), an input line for initializing a quantum state of each qubit, an output line for reading out a quantum state, and a pump line for adjusting a resonance frequency of the qubit with a SQUID are provided to perform quantum computation by combining multiple qubits. A scheme in which an input line and an output line are integrated as an input/output (IO) line by disposing a qubit with reflection-type arrangement, and a scheme in which multiple readout resonators are provided for multiple qubits, respectively and multiplexed readout is performed by connecting the multiple readout resonators to a single output line (readout line) are widely used.

In a quantum annealing computer, a network in which Josephson Parametric Oscillators (JPOs) are coupled with each other by four-body interaction is disclosed in NPL 1. In NPL 1, a JPO is denoted as JPA (Josephson Parametric Amplifier).

In the JPO, it is possible to adjust a resonance frequency by supplying a DC (Direct Current) current to a pump line coupled via a mutual inductance to the SQUID of the JPO. By applying a pump wave (AC (Alternating Current) current) to the pump line, an output signal wave (half frequency of the pump wave) is output from an input/output line due to oscillation (excitation). A relative phase of the output signal wave depends on an oscillation state of the JPO. The oscillation state can be controlled by an input signal wave.

JPOs may be arranged in a pyramidal square lattice pattern as illustrated in FIG. 9B. A product of two logical bits is redundantly embedded as a physical bit. This allows to represent an Ising problem of all-to-all connected logical bits by coupling of physical bits loosely coupled. FIG. 9A and FIG. 9B are diagrams based on FIG. 4b and FIG. 4c (Physical realization of the LHZ scheme) of NPL 1. In the LHZ (derived from Lechner, Hauke, Zoller) scheme, a problem that an optimization problem requires control of long-range interaction between many Ising spins is solved by mapping the Ising problem on a graph with local interactions. A pair of N logical spins is mapped to M=N (N−1)/2 physical spins. Logical spin pairs Jᵢ and Jⱼ (i≠j=1, . . . , N) are mapped to physical spins J′_{i,j} (J′_{i, j}=Jᵢ×Jⱼ) and J′_{i,j} are encoded in J′ₖ (e.g., J′_{1, 5} is encoded in J′₁, J′_{2,5} is encoded in J′₃, . . . ). In FIG. 9A, a graph structure of a fully-connected Ising model with N=5 logical spins is illustrated. FIG. 9B is a diagram in which the graph structure of the fully-connected Ising model with N=5 logical spins illustrated in FIG. 9A is mapped to M=10 physical spins. A circle O represents a coupler including Josephson junctions as non-linear elements (non-linear inductors) and four rectangles coupled thereto represent qubits (JPO). These configures a basic unit (“Plaquette”). In FIG. 9B, three physical bits below the lowest side physical bits are fixed bits (spin-fixed).

[NPL 1] S. Puri, et al., “Quantum annealing with all-to-all connected nonlinear oscillators,” Nature Communications, June 2017.

### SUMMARY

It is an object of the present disclosure to provide a quantum device with a wiring structure enabled to save wiring space of an array of a plurality of couplers and qubits to reduce an effect of crosstalk.

According to one aspect of the disclosure, there is provided a quantum device including a quantum chip including a two-dimensional array of a plurality of couplers and a plurality of qubits, on a wiring layer thereof, wherein the two-dimensional array of the quantum chip includes: a first unit region including a first coupler, a first qubit, a second coupler, and a second qubit on first to fourth vertices thereof in this order; and a second unit region including the first coupler, the second qubit, a third coupler, and a third qubit on first to fourth vertices thereof in this order, the first and fourth vertices in the first unit region being the first and second vertices in the second unit region, respectively.

The first unit region includes, therewithin: a capacitive coupling port of the second coupler disposed in a vicinity thereof; and an inductive coupling port of the second qubit disposed in a vicinity thereof, the second qubit being arranged adjacent to the second coupler.

The second unit region includes, therewithin: a capacitive coupling port of the second qubit disposed in a vicinity in a vicinity thereof; and an inductive coupling port of the third coupler disposed in a vicinity in a vicinity thereof, the third coupler being arranged adjacent to the second qubit.

According to the present disclosure, a quantum device provided with a wiring structure that enables saving wiring space of an array of a plurality of couplers and qubits and reducing an effect of crosstalk.

### BRIEF DESCRIPTION OF DRAWINGS

FIG. 1 is a schematic plan view illustrating one of example embodiments.

FIG. 2 is a schematic plan view illustrating one of example embodiments.

FIG. 3A is a diagram illustrating a qubit of one of example embodiments.

FIG. 3B is a diagram illustrating a coupler of one of example embodiments.

FIG. 4A is a diagram illustrating a signal connection of a qubit of one of example embodiments.

FIG. 4B is a diagram illustrating a signal connection of a coupler of one of example embodiments.

FIG. 5A is a diagram illustrating an example arrangement of a coupling ports of a qubit and a coupler of one of example embodiments.

FIG. 5B is a diagram illustrating an other example arrangement of a coupling ports of a qubit and a coupler of one of example embodiments.

FIG. 5C is a diagram illustrating an example of an arrangement illustrated in FIG. 5B.

FIG. 6 is a schematic plan view illustrating a wiring pattern of a three-dimensional wiring of one of example embodiments.

FIG. 7A is a schematic plan view illustrating a three-dimensional wiring of one of example embodiments.

FIG. 7B is a schematic cross-sectional view illustrating a three-dimensional wiring of one of example embodiments.

FIG. 8A is a schematic cross-sectional view illustrating an example of quantum chip mounting.

FIG. 8B is a schematic cross-sectional view illustrating an other example of quantum chip mounting.

FIG. 8C is a schematic perspective view illustrating an other example of quantum chip mounting.

FIG. 9A is a diagram cited from NPL 1.

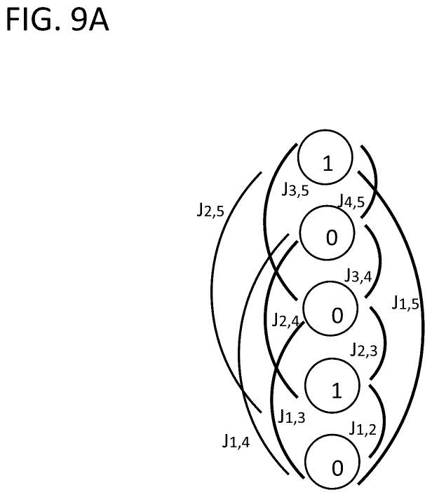

FIG. 9B is a diagram cited from NPL 1.

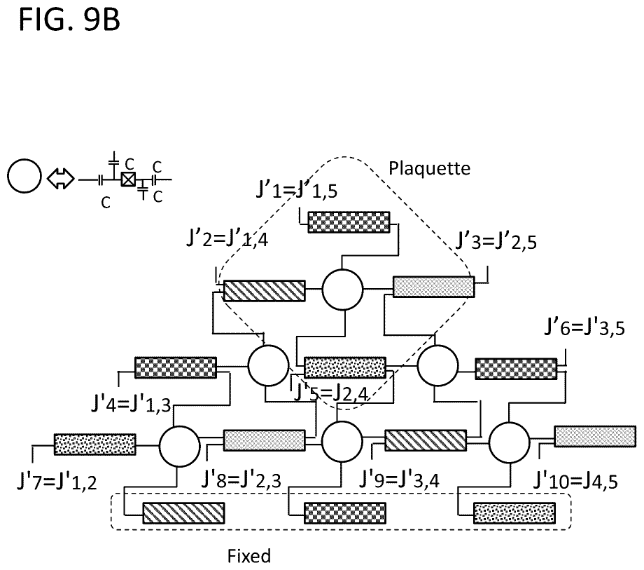

### EXAMPLE EMBODIMENTS

In the following description of examples, reference is made to the accompanying drawings which form a part hereof, and in which it is shown by way of illustration specific examples that can be practiced. It is to be understood that other examples can be used and structural changes can be made without departing from the scope of the disclosed examples. It is noted that in the disclosure, the expression “at least one of A and B” means A, B, or (A and B). The term expressed as “--(s)” includes both singular and/or plural form.

A four-body interaction coupler has an effect of excluding such an arrangement in which inverted conversion to logical bits is not enabled, which may occur by redundancy, by configuring coupled four bits as an even parity arrangement (even number of −1's). Although this scheme is loosely coupled, it is necessary to arrange wiring, for each qubit, an input/output line and a pump line. For each qubit, a signal wave close to a resonance frequency of the qubit is applied via the input/output line to the qubit and via the pump line, a DC (direct current) bias and/or a wave twice the frequency of the signal is applied to the qubit. In a case that a four-body interaction coupler is configured with a resonator that includes a SQUID (superconducting quantum interference device), a coupler also requires two lines of an input/output line and a control line (to which only a DC signal is applied). When implementing the four-body interaction coupler on an integrated circuit, wiring will become an issue. NPL1 proposed only a theoretical proposal, and there is no description of concrete specific configuration regarding wiring of a JPO network with a plurality of couplers. The above issue is one of examples. According to the present disclosure, which is not limited to the above issue, it is possible to provide a quantum device with an improved signal quality in various situations.

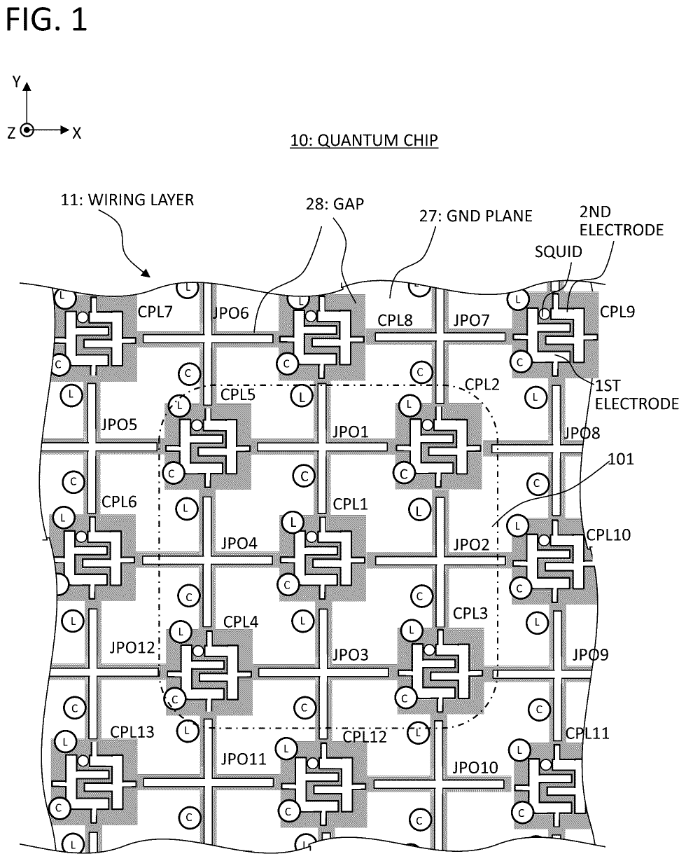

The following describes several examples of the present disclosure. FIG. 1 is a diagram illustrating one of examples. FIG. 1 is a schematic partial plan view of a planar circuit pattern of a wiring layer 11 (made of a superconducting material) on a substrate surface of a quantum chip 10, viewed from above. Each qubit is configured by a Josephson Parametric Oscillator (JPO). In FIG. 1, a qubit is indicated by JPO. In FIG. 1 and subsequent drawings, a qubit is indicated by “JPO” (or “JPO” followed by a “number”), and in the following descriptions, it is referred to as “JPO” (or “JPO” followed by a “number”) as appropriate. Also, a coupler is indicated by “CPL” (or “CPL” followed by a “number”), and in the following descriptions, it is referred to as “CPL” (or “CPL” followed by a “number”) as appropriate.

Referring to FIG. 1, there are provided a plurality of couplers (CPL1 to CPL13), each of which couples four nearest-neighbor qubits with a four-body interaction and a plurality of qubits (JPO1 to JPO12) on the wiring layer 11 formed on a substrate (not shown) of the quantum chip 10. A coupling port L and a coupling port C are provided for each JPO.

At the coupling port L of each JPO, a pump line (not shown) is inductively coupled (electro-magnetically coupled) to a SQUID (not shown) of each JPO. This coupling port L of each JPO may be referred to as an “inductive coupling port” of each JPO.

At the coupling port C of each JPO, a signal line (not shown) is capacitively coupled to each JPO. In FIG. 1, the signal line may be configured as an IO line in which a signal wave is supplied and output to and from each JPO). The coupling port C of each JPO may be referred to as a “capacitive coupling port” of each JPO. By applying a DC bias current from the pump line to the inductive coupling port L of each JPO, a DC bias magnetic flux is generated to enable adjusting a resonant frequency of each JPO. By applying a pump wave (AC current) from the pump line to the inductive coupling port L of each JPO, an output signal wave (with a half frequency of the pump wave) from each JPO due to oscillation of each JPO is output from the signal line which is the IO line. A relative phase of the output signal wave depends on an oscillation state of each JPO, which can be controlled by an input signal wave supplied to each JPO.

Each coupler (CPL) includes a first electrode and a second electrode which are spaced apart and opposed from each other. The first electrode is provided with a first opposing portion (protrusion portion) and a second opposing portion (protrusion portion), which are capacitively coupled to two of four nearest-neighbor qubits to the coupler, respectively. The second electrode is provided with a third opposing portion (protrusion portion) and a fourth opposing portion (protrusion portion), which are capacitively coupled to remaining two of the four nearest-neighbor qubits to the coupler, respectively. Each coupler (CPL) includes a SQUID which is bridged between the first electrode and the second electrode (as indicated by a small circle therebetween)

The coupling port L of each coupler (CPL) is arranged in a vicinity of the SQUID provided between the first electrode and the second electrode. The coupling port L includes an inductor which has one end connected to ground and the other end connected via a control line to an external direct current control part (not shown). The coupling port L of each coupler is referred to as an “inductive coupling port” of each coupler (CPL).

The coupling port C of each coupler (CPL) is arranged opposed to a side edge of the first electrode or the second electrode. The coupling port C is connected to one end of the signal line, which is the IO line, and the other end of the signal line is connected to an external signal source. The coupling port C of each coupler (CPL) is referred to as a “capacitive coupling port” of each coupler (CPL).

Each qubit (JPO) and each coupler (CPL) are surrounded by a ground plane (GND plane) via a gap, respectively. In FIG. 1, a wiring is of a three-dimensional wiring structure. The capacitive coupling ports Cs and the inductive coupling ports Ls of each qubit (JPO) and each coupler (CPL) are connected to a wiring substrate (interposer) (not shown) by bumps, respectively. On a wiring layer of the wiring substrate (interposer), wiring is routed to a connection terminal for an external connection. As a non-limiting example, a plurality of qubits (JPOs) and a plurality of couplers (CPLs) arranged on a two-dimensional array (grid) may configure a quantum annealing machine.

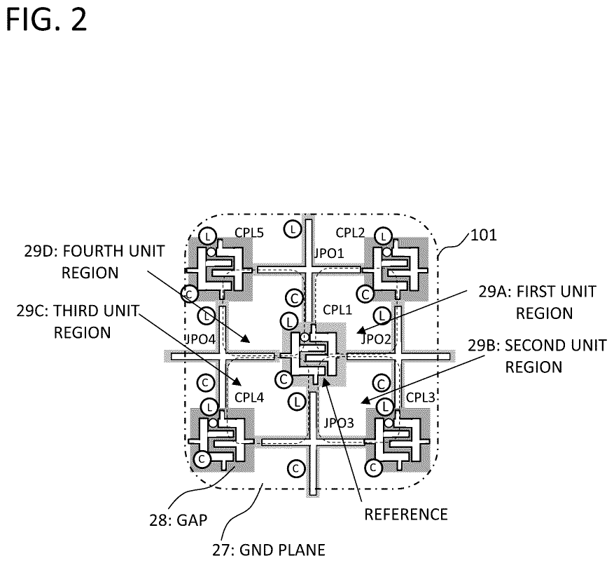

FIG. 2 is a diagram illustrating a partial region 101 of FIG. 1 enclosed by a single dotted line in which a coupler CPL1 and four nearest-neighbor qubits (JPO1 to JPO4) are provided. A set of the coupler and four nearest-neighbor qubits constitute a unit which is termed as “plaquette” in NPL1.

A two-dimensional array of the qubits (JPO1 to JPO4) and the couplers (CPL1 to CPL5) configured on a planar circuit includes a first unit region 29A and a second unit region 29B.

The first unit region 29A incudes, on first to fourth vertices thereof, the coupler CPL1, a qubit JPO1, a coupler CPL2, and a qubit JPO2 in this order (clockwise), with the coupler CPL1 set as a reference.

The second unit region 29B includes, on first to fourth vertices thereof, the coupler CPL1 of the first unit region 29A, the qubit JPO2 of the first unit region 29A, a coupler CPL3, and a qubit JPO3 in this order (clockwise).

The first and fourth vertices of the first unit region 29A are the first and second vertices of the second unit region 29B, respectively. The first unit region 29A and the second unit region 29B which are square-shaped may correspond respectively to the first quadrant and the fourth quadrant with the coupler CPL1 taken as an origin.

The first unit region 29A includes a capacitive coupling port C for the coupler CPL2 and an inductive coupling port L for the qubit JPO2 in a vicinity of the coupler CPL2 and the qubit JPO2, respectively, within its region.

The second unit region 29B includes capacitive coupling port C for the qubit JPO2 and an inductive coupling port L for the coupler CPL3 in a vicinity of the qubit JPO2 and the coupler CPL3, respectively, within its region.

Referring to FIG. 2, the two-dimensional array of the qubits (JPO1 to JPO4) and the couplers (CPL1 to CPL5) configured on the planar circuit includes a third unit region 29C and a fourth unit region 29D.

The third unit region 29C includes, on first to fourth vertices thereof, the coupler CPL1 of the first unit region 29A, a qubit JPO3 of the second unit region 29B, a coupler CPL4, and a qubit JPO4 in this order (clockwise).

The fourth unit region 29D includes, on first to fourth vertices thereof, the coupler CPL1 of the first unit region 29A, the qubit JPO4 of the third unit region 29C, a coupler CPL5, and the qubit JPO1 of the first unit region 29A are to be first to fourth vertices thereof in this order (clockwise).

The first vertex of the first unit region 29A and the fourth vertex of the second unit region 29B are the first vertex and the second vertex of the third unit region 29C, respectively.

The first vertex of the first unit region 29A, the fourth vertex of the third unit region 29C and the second vertex of the first unit region 29A are the first vertex, the second vertex and the fourth vertex of the fourth unit region 29D, respectively. The third unit region 29C and the fourth unit region 29D which are square-shaped may correspond respectively to the third quadrant and the second quadrant with the coupler CPL1 taken as the origin.

The third unit region 29C includes an inductive coupling port L for the qubit JPO3 and a capacitive coupling port C for the coupler CPL1 in a vicinity of the qubit JPO3 and the coupler CPL1, respectively, within its region.

The fourth unit region 29D includes a capacitive coupling port C for the qubit JPO1 and an inductive coupling port L for the coupler CPL1 in a vicinity of the qubit JPO1 and the coupler CPL1, respectively, within its region.

The first to fourth unit regions 29A to 29D are substantially square and are also unit lattices of a two-dimensional square lattice.

With the coupler CPL1 taken as the reference (origin), each of the first to fourth unit regions 29A to 29D located in first to fourth quadrants, respectively, includes either;
a capacitive coupling port C for the coupler CPL and an inductive coupling port L for the qubit JPO, or
a capacitive coupling port C for the qubit JPO and an inductive coupling port L for the coupler CPL, as a coupling port.

As for the first unit region 29A and the second unit region 29B, the capacitive coupling ports C and the inductive coupling ports L are arranged alternately in a clockwise direction, for example, as follows:
[the capacitive coupling port C for the coupler CPL2]→[the inductive coupling port L for the qubit JPO2]→[the capacitive coupling port C for the qubit JPO2]→[the inductive coupling port L for the coupler CPL3].

In a counterclockwise direction case, the inductive coupling ports L and the capacitive coupling ports C are arranged alternately.

As for the third unit region 29C and the fourth unit region 29D, the inductive coupling ports L and the capacitive coupling ports C are arranged alternately in a clockwise direction, for example, as follows:
[the inductive coupling port L for the qubit JPO3]→[the capacitive coupling port C for the coupler CPL1]→[the inductive coupling port L for the coupler CPL1]→[the capacitive coupling port C for the qubit JPO1].

In a counterclockwise direction case, the inductive coupling ports L and the capacitive coupling ports C are arranged alternately.

A signal (e.g., microwave signal) transmitted on a signal line connected to the capacitive coupling port C for the coupler CPL2 and a signal (e.g., microwave signal+DC signal) transmitted on a pump line connected to the inductive coupling port L for the qubit JPO2 have different frequency bands (Also, the power of each signal is different). Therefore, even if these ports (and thus the signal line of the coupler CPL2 and the pump line of the qubit JPO2) are arranged close to each other, an effect of crosstalk will not be an issue. The same applies to the capacitive coupling port C for the coupler CPL1 and the inductive coupling port L for the qubit JPO3.

Regarding a signal (e.g., microwave signal) transmitted on a signal line which has one end connected to the capacitive coupling port C for the qubit JPO2 and a signal (DC signal) applied to a control line which has one end connected to the inductive coupling port L for the coupler CPL3, there is no crosstalk between the control line (DC signal) and the signal line. A DC signal level of the control line is significantly higher than that of the signal line. Therefore, even if the control line (DC signal) and the signal line are arranged close to each other, an effect of crosstalk is not an issue. Accordingly, even if the capacitive coupling port C for the qubit JPO2 and the inductive coupling port L for the coupler CPL3 are arranged close to each other, an effect of crosstalk will not be an issue. The same applies to the inductive coupling port L for the coupler CPL1 and the capacitive coupling port C for the qubit JPO1.

As illustrated in FIG. 2, the inductive coupling port L for the coupler CPL2 (CPL5) and the inductive coupling port L for the coupler CPL3 (CPL4) are separated by a longitudinal length of the qubit JPO2 (JPO4) plus a substantially longitudinal length of the coupler CPL2 (CPL5) (e.g., 1.5 times a substantially lattice length), though not limited thereto.

The inductive coupling port L for the coupler CPL2 (CPL3) and the inductive coupling port L for the coupler CPL5 (CPL4) are spaced apart by a longitudinal length of the qubit JPO1 (JPO2) plus a substantially longitudinal length of the coupler CPL5 (CPL4) (e.g., 1.5 times a substantially lattice length), though not limited thereto.

In the examples in FIG. 1 and FIG. 2, each JPO has a cross-shaped electrode with four arms having the same length and width. Inductive coupling ports L of the two adjacent couplers are spaced apart, for example, by the size of the JPO (equivalent to two lattice lengths), though not limited thereto.

The inductive coupling port L for the coupler CPL1 is spaced apart from the inductive coupling port L of adjacent coupler CPL2 (or CPL5), for example, by about \sqrt{2} multiplied by a lattice length (substantially longitudinal length of each JPO), though not limited thereto.

Thus, by separating the inductive coupling ports L of couplers arranged adjacent to each other, an influence of a magnetic flux generated by the inductive coupling port L of one coupler (magnetic flux passing through the SQUID loop of the coupler) on the other coupler is suppressed.

The inductive coupling port L for the coupler CPL1 is separated from the inductive coupling port L of JPO1 by about twice the arm length of JPO1, is separated from the inductive coupling port L of JPO2 by a lattice length, is separated from the inductive coupling port L of JPO3 by the longitudinal length of the coupler CPL1, and is separated from the inductive coupling port L of JPO4 by the arm length of JPO4.

Thus, according to the examples of the present disclosure, the capacitive coupling ports and the inductive coupling ports can be arranged alternately as coupling ports for the qubits JPOs and the couplers CPLs to reduce the effect of crosstalk between the same type of lines.

Between different types of lines, the effect of crosstalk is smaller than between the same type of lines due to the difference in signal frequency between the qubit input/output line and the pump line. Therefore, they can be arranged closer to each other.

Thus, according to the present example embodiment, in the array of qubits and four-body interaction couplers, a combination of an arrangement of the inductive coupling ports L and the capacitive coupling ports C of the couplers CPL and the capacitive coupling ports C and the inductive coupling ports L of the qubits JPO in the lattice is made to have regularity, which enables to suppress an effect of crosstalk between signals while achieving saving wiring space.

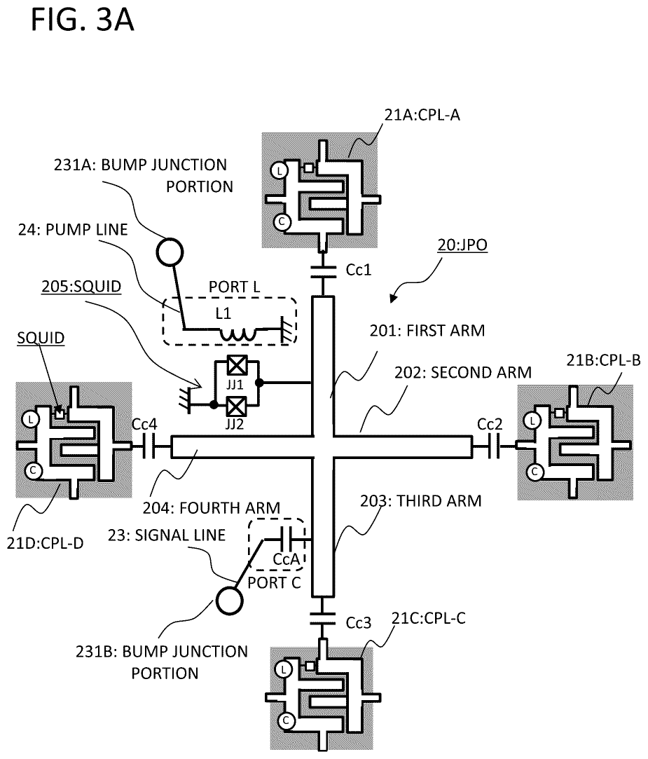

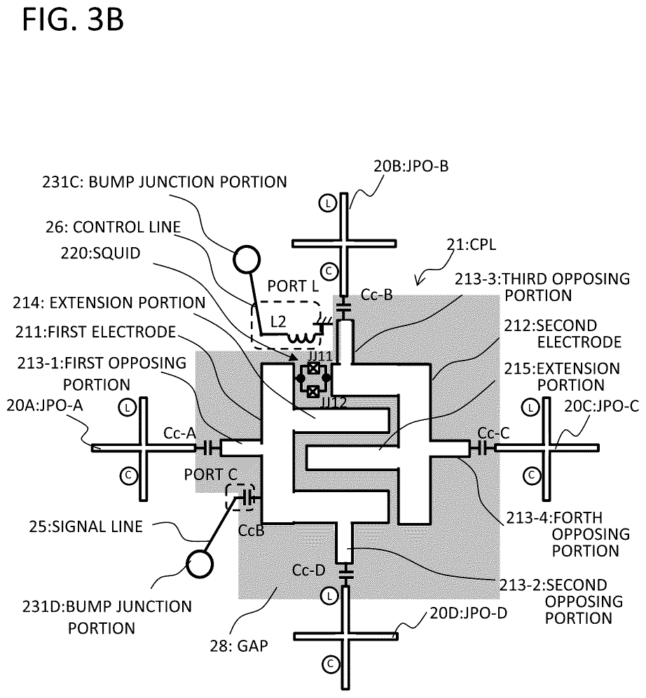

FIG. 3A is a diagram illustrating a non-limiting example of a signal connection of the qubit (JPO) illustrated in FIG. 1. In a JPO20, a cross-shaped electrode provided with first to fourth arms 201 to 204 has an inductance component, and a capacitance component between the electrode and the ground. JPO20 includes SQUID 205 (including Josephson junctions JJ1 and JJ2 in the loop) connected between one side edge of the first arm 201 and the ground. A capacitance (parasitic capacitance) (not shown) is connected in parallel to the SQUID 205 between the first arm 201 and the ground.

An inductive coupling port L for the JPO20 includes a magnetic field generation portion (inductor L1) at one end side of a pump line 24 which has the one end connected to the ground and the other end connected to a current control part (not shown). At the inductive coupling port L for the JPO20, a pump wave (microwave signal and DC bias signal) supplied from a pump terminal (not shown) to the pump line 24 generate a magnetic flux (magnetic field) passing through the loop of the SQUID 205. In FIG. 3A, the SQUID includes two Josephson junctions JJ1 and JJ2 in the loop. The SQUID can, as a matter of course, be configured to include three or more Josephson junctions.

A signal line 23 (IO line) is capacitively coupled to one side edge of the third arm 203 of the cross-shaped electrode of the JPO20 through a coupling capacitor Cc. That is, a capacitive coupling port C of the JPO20 includes a coupling capacitance CcA between one end of the signal line 23 and an opposed side edge of the third arm 203 of the JPO20. The signal line 23 and the pump line 24 are connected to a wiring layer of an interposer substrate (not shown) via bumps (e.g., metal protrusions not shown) at bump junction portions (pads) 231B and 231A, respectively.

FIG. 3B is a diagram illustrating a non-limiting example of a signal connection of the coupler (CPL) illustrated in FIG. 1. A coupler (CPL) 21 includes a SQUID 220 (loop including Josephson junctions JJ11 and JJ12) between a first electrode 211 and a second electrode 212 opposing each other. A capacitance component (not shown) between the first electrode 211 and the second electrode 212 is connected in parallel with the SQUID 220. A magnetic field generation portion (inductor L2) of a control line 26 which has one end connected to ground, in response to a DC signal (DC current) supplied from a pump terminal, generates a magnetic flux (magnetic field) passing through the loop of the SQUID 220 of the coupler. The magnetic field generation portion (inductor L2) of the control line 26 configures an inductive coupling port L for the coupler. A signal line 25 is capacitively coupled to the first electrode 211 through a coupling capacitor Cc. A capacitive coupling port C for the coupler includes a capacitance CcB of a gap between one end of the signal line 25 and an opposed side edge of the first electrode 211. The first electrode 211 is provided with first and second opposing portions (protrusion portions) 213-1 and 213-2. The second electrode 212 is provided with third and fourth opposing portions (protrusion portions) 213-3 and 213-4. The first and second opposing portions (protrusions) 213-1 and 213-2 face one end of each of arms of the cross-shaped electrodes of JPO-A and JPO-D, respectively, and are coupled thereto via coupling capacitors Cc-A and Cc-D, respectively. The third and fourth opposing portions (protrusions) 213-3 and 213-4 face one end of each of arms of the cross-shaped electrodes of JPO-B and JPO-C, respectively, and are coupled thereto via coupling capacitors Cc-B and Cc-C, respectively. In an example illustrated in FIG. 3B, substantially L-shaped electrode 211 and substantially inverted L-shaped electrode 212 are arranged opposing each other, and an extension portion 214 extended toward opposing side from the first electrode 211 and an extension portion 215 extended toward opposing side of the first electrode 211 from the second electrode are arranged in a nested structure. A configuration in which the first electrode 211 and the second electrode 212 have nested extension portions 214 and 215 has a larger capacitance value between the first electrode 211 and the second electrode 212 than a configuration without extension portions 214 and 215. The first electrode 211 and the second electrode 212 may have a plurality of extension portions 214 and a plurality of extension portions 215, respectively, and they may be arranged to form a comb-teeth like inter-digital structure. The shape of the first and second electrodes 211 and 212 of the coupler (CPL) is, as a matter of course, not limited to a substantially L-shape or a substantially inverted L-shape.

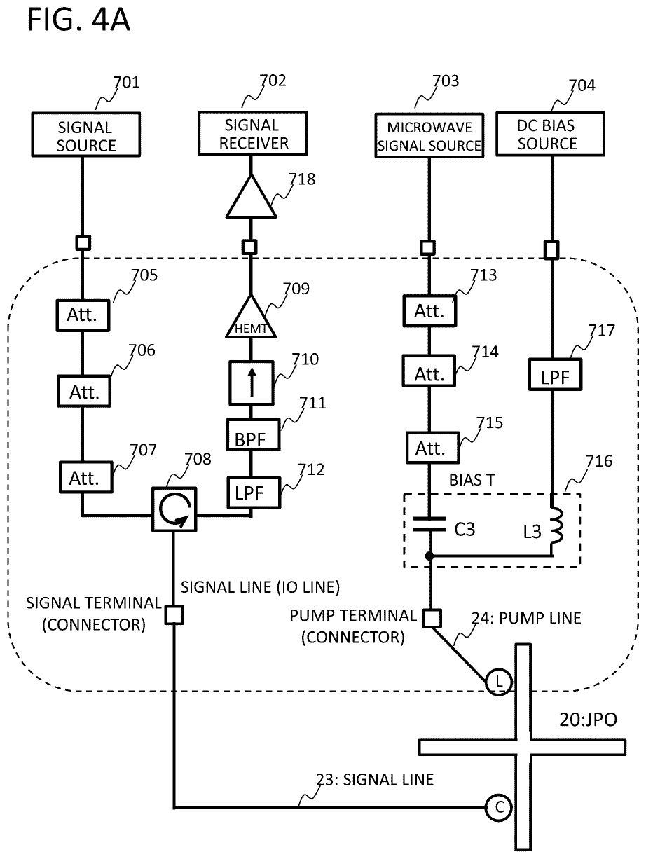

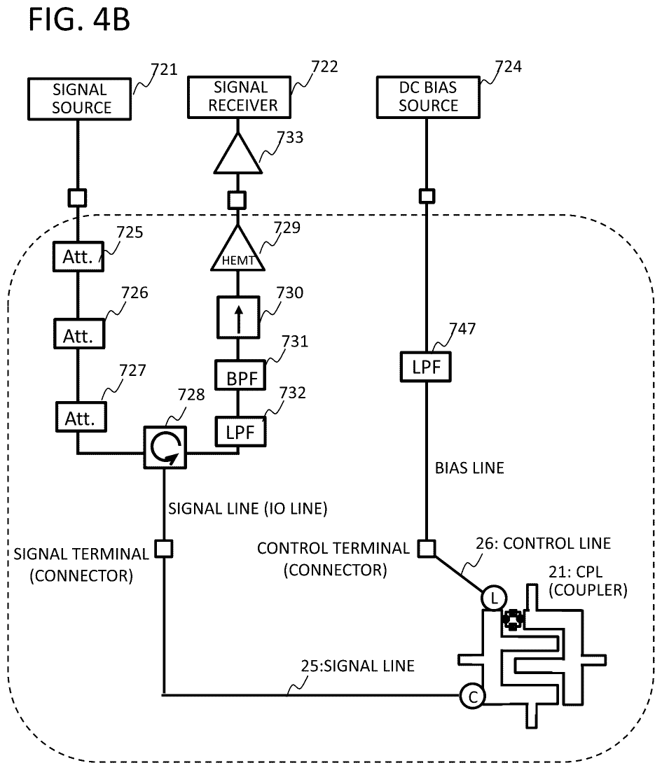

FIG. 4A is a diagram illustrating an example of a connection configuration of a signal terminal (IO terminal) and a pump terminal to which a signal line and a pump line of the JPO are connected respectively, and measurement electronics outside a refrigerator. The IO line has one end connected to the JPO20 via a coupling capacitor Cc, and the other end connected to a circulator 708 via the signal terminal (IO terminal). A signal from a signal source 701 outside a dilution refrigerator is transmitted through a coaxial cable which is led into the dilution refrigerator, is attenuated gradually by attenuators (Atts.) 705, 706, and 707 installed at respective temperature stages, is transmitted, via the circulator 708, to the signal terminal (IO terminal), and is supplied through the signal line 23 to the capacitive coupling port C of the JPO20. An output signal wave from the JPO20 or a reflection signal of an input signal wave from the JPO20 is transmitted to the signal terminal (IO terminal) via the signal line 23 and it is transmitted from the signal terminal (IO terminal) via the circulator 708, a Low Pass Filter (LPF) 712, a Band Pass Filter (BPF) 711, an isolator 710 and a HEMT (High Electron Mobility Transistor) amplifier 709 to an amplifier 718 outside the dilution refrigerator, which supplies an amplified signal to a signal receiver 702. A pump signal (microwave continuous wave or pulsed wave) from a microwave signal source 703, which generates the pump signal (microwave signal), is transmitted through a coaxial cable which is led into the dilution refrigerator, attenuated gradually by attenuators 713, 714, and 715 installed at respective temperature stages and supplied to a bias T circuit 716. A DC (Direct Current) signal from a DC bias source 704 is supplied through a transmission line (e.g., twisted pair) which is led into the dilution refrigerator to the bias T circuit 716 via an LPF 717. The bias T circuit 716 includes a capacitor C3 and an inductor L3 (choke coil). The capacitor C3 has one end to receive a microwave from the microwave signal source 703. The inductor L3 (choke coil) has one end to receive the DC signal from the DC bias source 704 via the LPF 717. In the bias T circuit 716, a connection point of other ends of the capacitor C3 and the inductor L3 is connected to a pump line. The bias T circuit 716 superimposes (combines) a direct current signal on a high-frequency signal by combining the capacitor C3 and the inductor L3 (choke coil). The capacitor C3 passes only high frequencies. The inductor L3 passes a direct current and currents having lower frequencies than a prescribed frequency and blocks currents having higher frequencies than the prescribed frequency. The superimposed signal is supplied to a pump line and led into the inductive coupling port L. The JPO can perform parametric oscillation at a frequency (angular frequency) ω by supplying a DC bias signal and a pump signal to a pump line 24 from the microwave signal source 703. The DC bias signal is a signal that biases the SQUID in the JPO with a DC magnetic flux. The pump signal is a signal with a frequency about twice the resonant frequency (angular frequency) w of the SQUID resonator.

FIG. 4B is a diagram illustrating an example of a connection configuration of a signal terminal (IO terminal) and a control terminal to which a signal line and a pump line of the coupler CPL connects respectively, and measurement electronics outside a refrigerator. A signal line 25 has one end connected to a capacitive coupling port C of a CPL21 and the other end connected to a circulator 728 via the signal terminal (IO terminal). A signal from a signal source 721 outside a dilution refrigerator is transmitted through a coaxial cable which is led into the dilution refrigerator, is attenuated gradually by attenuators (Atts.) 725, 726, and 727 installed at respective temperature stages, is transmitted to the signal terminal (IO terminal) via the circulator 728, and is supplied to the capacitive coupling port C for the coupler 21 from the signal line 25. A reflection signal of an input signal wave from the coupler 21 is transmitted to the signal terminal (IO terminal) via the signal line 25 and it is transmitted from the signal terminal (IO terminal) via the circulator 728, a Low Pass Filter (LPF) 732, a Band Pass Filter (BPF) 731, an isolator 730 and a HEMT amplifier 729 to an amplifier 733 outside the dilution refrigerator, which supplies an amplified signal to a signal receiver 722. A DC signal from a DC bias source 724 is transmitted through a transmission line (e.g., twisted pair) which is led into the dilution refrigerator, supplied to the control terminal via an LPF 747, from which the DC signal is supplied via the control line 26 to an inductive coupling port L for the coupler.

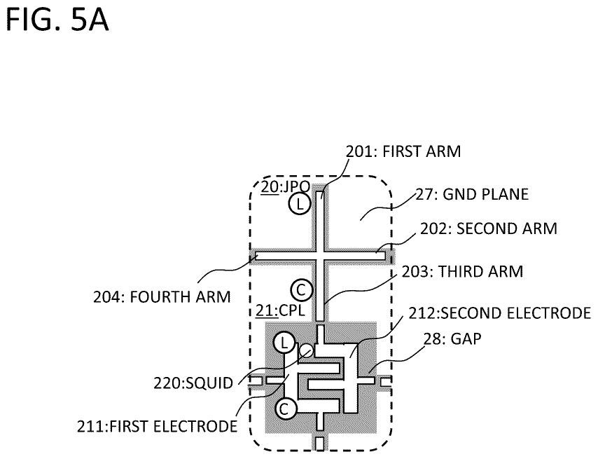

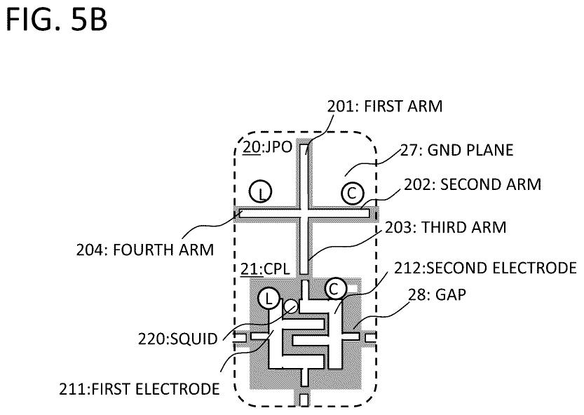

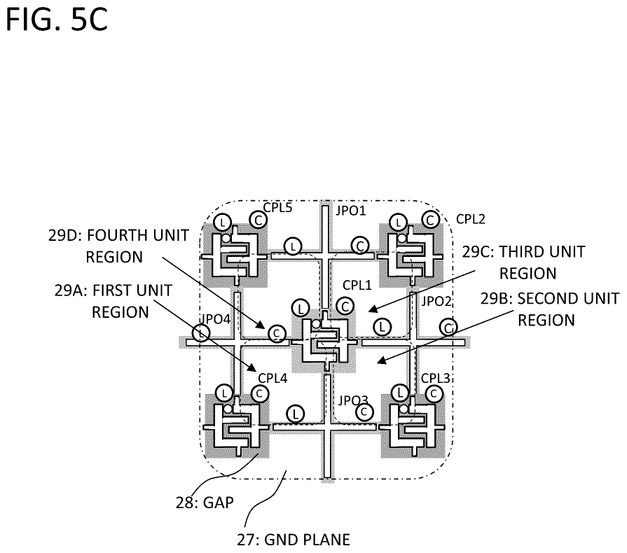

FIG. 5A is a diagram illustrating a combination of coupling ports arrangements of the qubit JPO20 and the coupler CPL21, corresponding to an arrangement example described with reference to FIG. 1 and FIG. 2.

An inductive coupling port L on a side (left side in the drawing) of a first arm 201 of the JPO20, a capacitive coupling port C on a side (left side in the drawing) of a third arm opposite to the first arm 201, and an inductive coupling port L and a capacitive coupling port C on a first electrode 211 side of the CPL21 are arranged in this order in a vertical direction in the drawing.

A coupling between the qubit JPO20 and the inductive coupling port L to which the pump line is connected and a coupling between the qubit JPO 20 and the capacitive coupling port C to which the signal line (IO line) is connected may be made on the same plane as the wiring layer 11 of the quantum chip 10 on which the qubit is formed. Alternatively, they may be configured three-dimensionally between wiring layers using multilayer wiring. In the coupler CPL21, the inductive coupling port L is disposed near the SQUID of the coupler CPL21. The capacitive coupling port C to which an input/output line is connected can be placed in a line-symmetrical position with the inductive coupling port L. A coupling between the coupler and the control line and a coupling between the coupler and the input/output line can be configured to be made on the same plane, or they may be configured three-dimensionally between wiring layers using multilayer wiring.

FIG. 5B is a diagram illustrating the other combination of coupling ports arrangements of the qubit JPO20 and the coupler CPL21. An inductive coupling port L on a side (upper side in the drawing) of a fourth arm 204 of the JPO20 and a capacitive coupling port C on a side (upper side in the drawing) of a second arm opposite to the fourth arm 204 are arranged in this order in a lateral direction in the drawing. Also, an inductive coupling port L on an upper side of the first electrode 211 of the coupler 21 and a capacitive coupling port C on an upper side of the second electrode 212 are arranged in parallel to the inductive coupling port L and the capacitive coupling port C of the JPO in a lateral direction in the drawing.

Locations of the capacitive coupling port C and the inductive coupling port L for the qubit JPO may be arranged to be a combination of either illustrated in FIG. 5A or FIG. 5B, depending on locations of the capacitive coupling port C and the inductive coupling port L for the coupler CPL.

FIG. 5C is a diagram illustrating an arrangement of capacitive coupling ports C and inductive coupling ports L of couplers and four nearest-neighbor qubits, when the capacitive coupling ports C and the inductive coupling ports L of the qubit JPO and the coupler CPL are arranged to be the combination illustrated in FIG. 5B.

Referring to FIG. 5C, a two-dimensional array of qubits and couplers is provided with a first unit region 29A and a second unit region 29B.
In the first unit region 29A, the coupler CPL1, a qubit JPO4, a coupler CPL4, and a qubit JPO3 are to be first to fourth vertices thereof in this order (clockwise), with the coupler CPL1 as reference.
In the second unit region 29B, the coupler CPL1 of the first unit region 29A, the qubit JPO3 of the first unit region 29A, a coupler CPL3, and a qubit JPO2 are to be first to fourth vertices thereof in this order (clockwise).

The first and fourth vertices of the first unit region 29A are the first and second vertices of the second unit region 29B, respectively.

The first unit region 29A is provided with a capacitive coupling port C for the coupler CPL4 and an inductive coupling port L for the qubit JPO3 in a vicinity of the coupler CPL4 and the qubit JPO3, respectively, within its region.

The second unit region 29B is provided with a capacitive coupling port C for the qubit JPO3 and an inductive coupling port L for the coupler CPL3 in a vicinity of the qubit JPO3 and the coupler CPL3, respectively, within its region.

The two-dimensional array of qubits and couplers is further provided with a third unit region 29C and a fourth unit region 29D.
In the third unit region 29C, the coupler CPL1 of the first unit region 29A, a qubit JPO2 of the second unit region 29B, a coupler CPL2, and a qubit JPO1 are to be first to fourth vertices thereof in this order (clockwise).
In the fourth unit region 29D, the coupler CPL1 of the first unit region 29A, the qubit JPO1 of the third unit region 29C, a coupler CPL5, and the qubit JPO4 of the first unit region 29A are to be first to fourth vertices thereof in this order (clockwise).

The first vertex of the first unit region 29A and the fourth vertex of the second unit region 29B are the first vertex and the second vertex of the third unit region 29C, respectively. The first vertex of the first unit region 29A, the fourth vertex of the third unit region 29C and the fourth vertex of the first unit region 29A are the first vertex, the second vertex and the fourth vertex of the fourth unit region 29D, respectively.

The third unit region 29C is provided with a capacitive coupling port C for the coupler CPL1 and an inductive coupling port L for the qubit JPO2 in a vicinity of the coupler CPL1 and the qubit JPO2, respectively, within its region.

The fourth unit region 29D is provided with a capacitive coupling port C for the qubit JPO4 and an inductive coupling port L for the coupler CPL1 in a vicinity of the qubit JPO4 and the coupler CPL1, respectively, within its region.

As for the first unit region 29A and the second unit region 29B, the capacitive coupling ports C and the inductive coupling ports L are arranged alternately in a counterclockwise direction, for example, as follows:
[the capacitive coupling port C for the coupler CPL4]→[the inductive coupling port L for the qubit JPO3]→[the capacitive coupling port C for the qubit JPO3]→[the inductive coupling port L for the coupler CPL3].

As for the third unit region 29C and the fourth unit region 29D, the capacitive coupling ports C and the inductive coupling ports L are arranged alternately in a counterclockwise direction, for example, as follows:
[the capacitive coupling port C for the qubit JPO4]→[the inductive coupling port L for the coupler CPL1]→[the capacitive coupling port C for the coupler CPL1]→[the inductive coupling port L for the qubit JPO2].

In the configuration illustrated in FIG. 5C, as with that illustrated in FIG. 2, the capacitive coupling ports and the inductive coupling ports can be arranged alternately, as coupling ports for the qubits JPOs and the couplers CPLs to reduce the effect of crosstalk between the same type of lines. Thus, in the array of qubits and four-body interaction couplers, a combination of an arrangement of the inductive coupling ports L and the capacitive coupling ports C of the couplers CPL and the capacitive coupling ports C and the inductive coupling ports L of the qubits JPO in the lattice is made to have regularity, which enables to suppress an effect of crosstalk between signals while achieving saving wiring space.

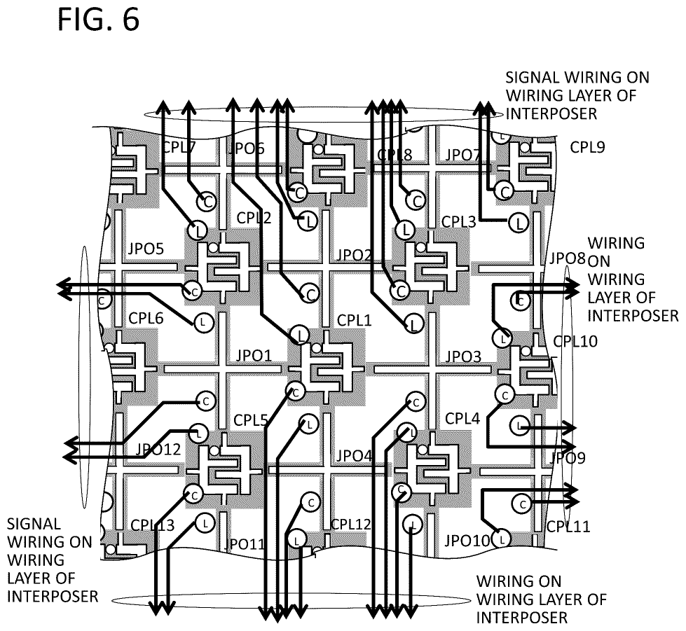

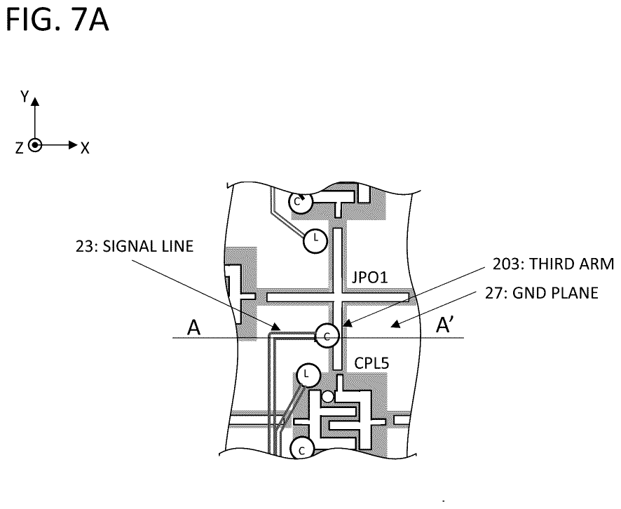

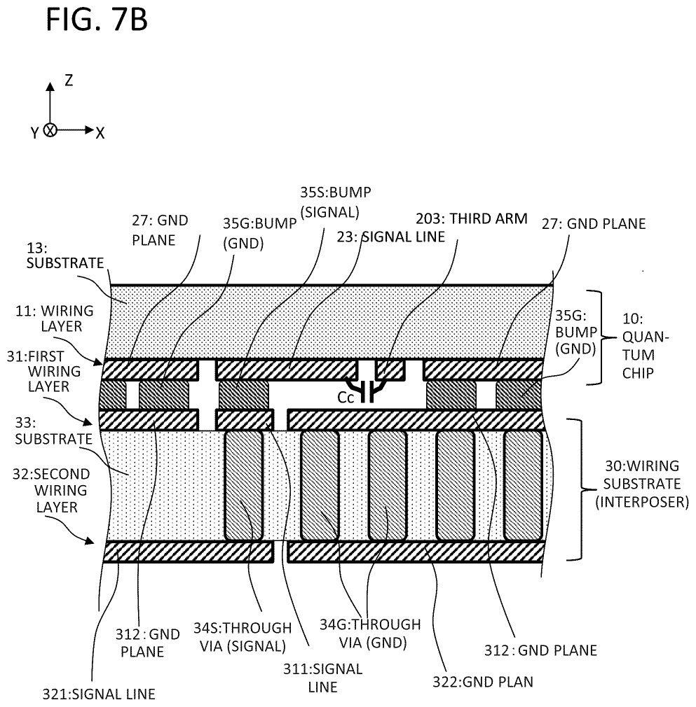

FIG. 6 is a diagram schematically illustrating an example of a three-dimensional wiring structure in the quantum chip 10. FIG. 6 schematically illustrates an example of wiring (signal line 321 in FIG. 7B) on a wiring layer of a wiring substrate (interposer) arranged opposing the quantum chip 10. More specifically, the qubit JPO and each capacitive coupling port C and inductive coupling port L for the coupler

CPL, on a wiring layer of the quantum chip 10, are connected to the wiring layer of the substrate (interposer) by bump (not shown) from each wiring pad (bump junction portions 231A, 231B, 231C, and 231D in FIG. 3A and FIG. 3B). Then, the wiring is routed from the wiring layer of the substrate (interposer) to outside (external equipment(s)).

In FIG. 6, on the upper side of the drawing, lines are arranged from left to right in the following order:
a pump line connected to an inductive coupling port L of a coupler CPL2;
a signal line connected to a capacitive coupling port C of a JPO6;
a control line connected to an inductive coupling port L of a coupler CPL 1;
a signal line connected to a capacitive coupling port C of a JPO2;
a pump line connected to an inductive coupling port L for the JPO2;
a signal line connected to a capacitive coupling port C for the coupler CPL2;
a pump line connected to an inductive coupling port L of a JPO3;
a signal line connected to a capacitive coupling port C of a coupler CPL3;
a control line connected to an inductive coupling port L for the coupler CPL3;
a signal line connected to a capacitive coupling port C of a JPO7; a pump line connected to an inductive coupling port L of a JPO8, and
a signal line connected to a capacitive coupling port C of a coupler CPL9.

That is, lines connected to inductive coupling ports L and lines connected to capacitive coupling ports C are arranged alternately, for inductive coupling ports L of couplers, capacitive coupling ports C of JPOs, inductive coupling ports L of qubits JPOs, and capacitive coupling ports C of couplers.

In FIG. 6, on the bottom side of the drawing, lines are arranged in this order from left to right in the following order;
a signal line connected to a capacitive coupling port C of a coupler CPL5;
a pump line connected to an inductive coupling port L of a JPO11;
a signal line connected to a capacitive coupling port C of a coupler CPL1;
a pump line connected to an inductive coupling port L of a JPO4;
a signal line connected to a capacitive coupling port C of the JPO4;
a control line connected to an inductive coupling port L of a coupler CPL12;
a signal line connected to a capacitive coupling port C of a JPO3; a control line connected to an inductive coupling port L of a coupler CPL4;
a signal line connected to a capacitive coupling port C for the coupler CPL4; and
a pump line connected to an inductive coupling port L of a JPO10.

That is, lines connected to inductive coupling ports L and lines connected to capacitive coupling ports C are arranged alternately, for inductive coupling ports L of couplers, capacitive coupling ports C of JPOs, inductive coupling ports L of qubits JPOs, and capacitive coupling ports C of couplers.

In FIG. 6, lines connected to capacitive coupling ports C and lines connected to inductive coupling ports L are arranged alternately on the left and right sides of the drawing as well. In FIG. 6, each wiring (signal line, pump line and control line) is preferably configured with a coplanar waveguide or a strip line in both the wiring layer of the quantum chip 10 and the wiring layer of the wiring substrate (interposer). The pad (bump pad, via pad, or bonding pad, etc.) to which the wiring is connected is also surrounded by a ground plane.

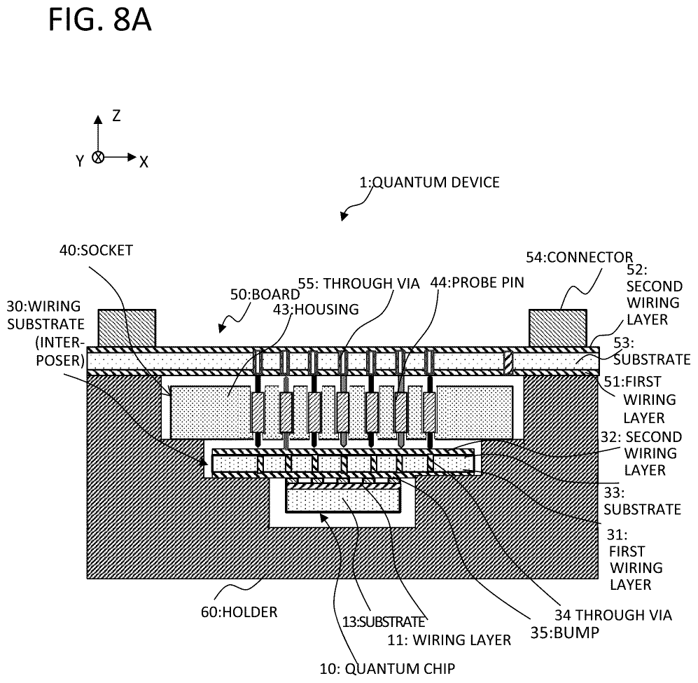

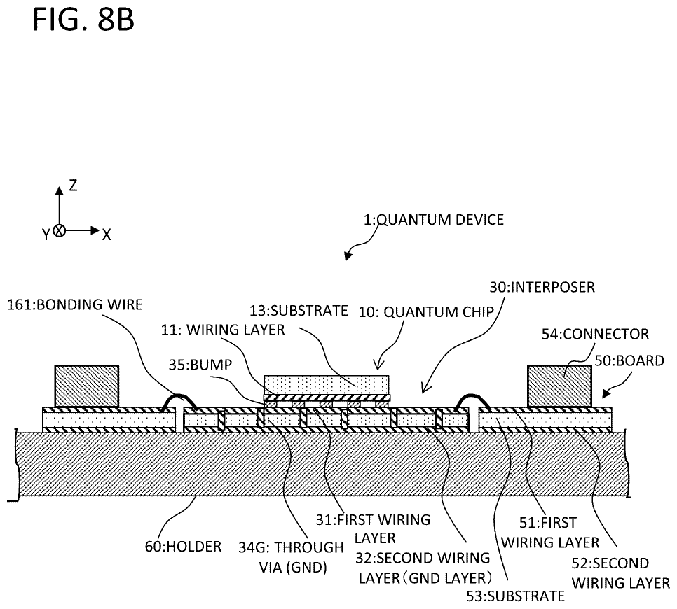

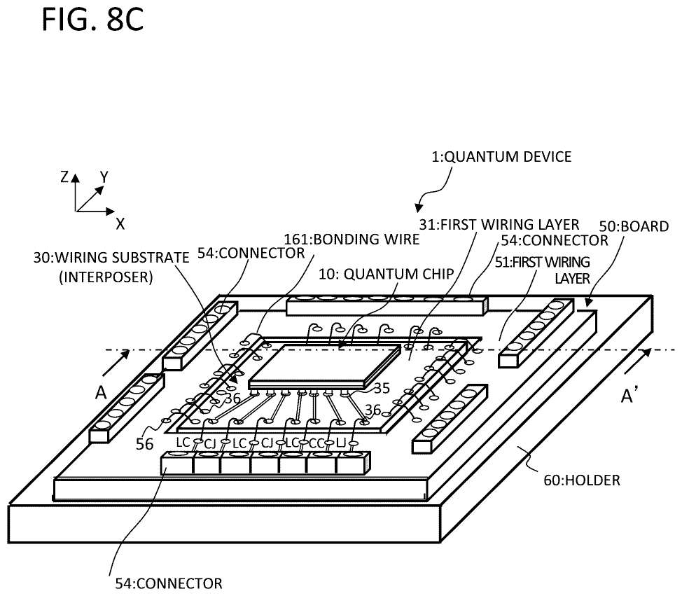

FIG. 7A and FIG. 7B are diagrams illustrating examples of three-dimensional wiring structures. FIG. 7A is a partial plan view of a vicinity of the JPO1 illustrated in FIG. 6. FIG. 7B is a schematic cross-sectional view illustrating cross section of line A-A′ in FIG. 7A. Referring to FIG. 8B, the wiring layer 11 of the quantum chip 10 is faced to a first wiring layer 31 on a wiring substrate (interposer) 30 and connected thereto via bumps.

As a material of a substrate 13 of the quantum chip 10, for example, silicon (Si) may be used, but other electronic materials such as sapphire or a compound semiconductor material (group IV, group III-V and group II-VI) may be used. The substrate 13 is preferably a single crystal but may be a polycrystalline or amorphous. A pattern on the wiring layer 11 of the quantum chip 10 may be formed by deposition (vapor deposition) of a superconducting material on a surface of the substrate 13 and patterning the superconducting material. As a superconducting material (wiring material), Nb (niobium) or Al (aluminum) may be used, though not limited thereto. Any metal that becomes superconductive at an extremely low temperature (cryogenic temperature) may be used, such as niobium nitride, indium (In), lead (Pb), tin (Sn), rhenium (Re), palladium (Pd), titanium (Ti), titanium nitrides, molybdenum (Mo), tantalum (Ta), tantalum nitride, and an alloy containing at least one of the above metals. As a non-limiting example, Josephson junctions (Al/AlOₓ/Al) may be formed by forming a first aluminum film on a surface of the substrate by oblique deposition, oxidizing the first aluminum film to form a tunnel oxide film (AlOₓ), and then forming a second aluminum film by oblique deposition from a direction opposite to a direction when the first aluminum film was formed.

The wiring layer 11 of the quantum chip 10 includes a wiring pattern of a superconducting quantum circuit and ground plane 27 (ground pattern). The signal line (IO line) 23 is configured as a coplanar waveguide with ground planes on both longitudinal direction sides. Couplers CPLs and qubits JPOs are surrounded by ground plane 27 via gaps. In the wiring layer 11, the third arm 203 of the JPO1 is coupled to of the signal line 23 via a gap with a capacitance Cc.

The first wiring layer 31 of the wiring substrate (interposer) 30 is faced to the wiring layer 11 of the quantum chip 10 and connected thereto via bumps (metal protrusions) 35G and 35S. More specifically, a signal pad of the wiring layer 11 of the quantum chip 10 is directly connected to a signal pad of the first wiring layer 31 of the wiring substrate (interposer) 30 with the bump (metal protrusion) 35S. The ground plane 27 of the wiring layer 11 of the quantum chip 10 is directly connected to a ground plane 312 of the first wiring layer 31 of the wiring substrate (interposer) 30 with the bump (metal protrusion) 35G. The bumps 35G arranged around the quantum chip 10 contributes to crosstalk reduction. The ground plane 27 of the wiring layer 11 of the quantum chip 10 and the ground plane 312 of the first wiring layer of the wiring substrate (interposer) 30 are connected by multiple bumps 35G at multiple locations. The bumps 35S and 35G may be formed on the first wiring layer 31 of the wiring substrate (interposer) 30. Alternatively, they may be formed on a side of the wiring layer 11 of the quantum chip 10.

Each of the bumps 35S and 35G has a protrusive shape suited to height control of inter-substrate spacing to be bonded, and any shape can be selected, such as columnar (cylindrical, polygonal, etc.), pyramidal (which can include a truncated cone and a truncated pyramid as well as a cone, and a pyramid, etc.), spherical, rectangular, etc. Each of the bumps 35S and 35G may include normal-conducting material and laminated superconducting materials. Each of the bumps 35S and 35G may include the same superconducting material as the first wiring layer 31 of the wiring substrate (interposer) 30. Alternatively, they may include a superconducting material different from that of the first wiring layer 31.

As for the bumps 35S and 35G with multiple metal layers, it is preferable that at least one layer of the bumps 35S and 35G includes a superconducting material. The bumps 35S and 35G may have a layered structure including Nb/In (Sn, Pb, or an alloy including at least one of Sn or Pb)/Ti/Nb (a surface of the wiring layer 11 of the interposer 30) /Cu, a layered structure including Nb (a surface of the first wiring layer 31 of the interposer 30) Nb (the surface of the wiring layer 11 of the quantum chip 10) /Cu, or a layered structure including /Nb (the surface of the first wiring layer 31 on the wiring substrate 30) /In (Sn, Pb, or an alloy including at least one of Sn or Pb) /Ta (the surface of the wiring layer 11 of the quantum chip 10) /Cu. Further, in case where the bumps 35S and 35G include Al and In, TiN may be used for a barrier layer to prevent alloying of Al and In. In such a case, the bumps 35S and 35G may have layered structures including Al (the surface of the first wiring layer 31 of the wiring substrate (interposer) 30) /Ti/TiN/In (Sn, Pb, or an alloy including at least one of Sn or Pb) /TiN/Ti/Al (the surface of the wiring layer 11 of the quantum chip 10) /Cu, where Ti is an adhesion layer. A flip-chip connection is preferably implemented by Nb (the surface of the first wiring layer 31 of the interposer 30) /In/Ti/Nb (the surface of the wiring layer 11 of the quantum chip 10) /Cu, or Nb (the surface of the first wiring layer 31 of the wiring substrate (interposer) 30) /Nb (the surface of the wiring layer 11 of the quantum chip 10) /Cu. Alternatively, each of the bumps 35S and 35G is made of a normal conducting material such as Cu or silicon dioxide (SiO2), and may have a surface thereof covered with a film of a superconducting material.

As a non-limiting example, a width of each of the bumps 35S and 35G may be on an order of a few or several to a few or several tens of micrometers, and a height of each of the bumps 35S and 35G may be on an order of a few or several to a few or several tens of micrometers. The quantum chip 10 and the bumps 35S and 35G may be bonded using such as solid phase bonding. Regarding solid-phase bonding methods, surface activation bonding SAB or ultrasonic bonding may be used. Alternatively, melt joining may be used in a case where high temperature can be applied during bonding. Pressure welding may be used in a case where a resin can be used.

In a case where the substrate 13 of the quantum chip 10 is silicon, silicon may be used for a substrate 33 of the wiring substrate (interposer) 30 in consideration of a linear expansion coefficient, etc. In this case, the wiring substrate (interposer) 30 may be also referred to as a silicon interposer. The substrate 33 is not limited to one including silicon. The substrate 33 may include other electronic materials such as sapphire or compound semiconductor materials (group IV, III-V and II-VI), glass, and ceramics. The bumps 35S and 35G may be formed on the first wiring layer 31 during a fabrication process of the wiring substrate (interposer) 30.

A signal pad (signal line 23) of the first wiring layer 31 of the wiring substrate (interposer) 30 and the ground plane 312 are connected to a signal line 321 of a second wiring layer 32 on the reverse side and a ground plane 322 via through vias 34S and 34G, respectively. The second wiring layer 32 of the wiring substrate (interposer) 30 is preferably made of the same superconducting material as the first wiring layer 31. The through vias 34S and 34G are illustrated as filled vias, but may, as a matter of course, be conformal vias. The filled via is a via with a via hole filled with a conductive material and the conformal via is a via with a conductive material formed with a constant thickness along a shape of a via hole. A conductive material of the via hole may of course be a superconducting material. In the second wiring layer 32 of the wiring substrate (interposer) 30, a wiring may be routed from the through via 34S to connect to connection terminals (pad) for connection to the outside. In FIG. 7B, a through via 34S is disposed directly under a bump 35S via a signal line 311 in the wiring substrate (interposer) 30. However, it is of course possible to shift and arrange the through via 34S at a different position than directly under the bump 35S, for example, by extending the signal line 311 connecting to the bump 35S.

In general, as a signal propagates, a return current is generated in its vicinity. If there is no return path (path for return current to flow) around the through via 34S that transmits signals, the through via 34S becomes an antenna, for example, and causes resonance. This further may generate radiation noise at a specific frequency, which may interfere with a signal via located nearby to generate crosstalk. Therefore, in the present implementation example, the through via 34S, which is a signal via, is guarded by arranging a plurality of through vias 34G (ground vias) connected to ground (ground plane), around the through via 34S on which a signal is transmitted.

In FIG. 7B, a wiring (for example, signal line 321) may be routed to connection terminals (pad) for external connection in the second wiring layer 32 of the wiring substrate (interposer) 30. However, the wiring may be routed on the first wiring layer 31 of the wiring substrate (interposer) 30, and the second wiring layer 32 may be a ground layer.

FIG. 8A is a diagram schematically illustrating an example of a configuration of the quantum chip 10 for external connection. The quantum chip 10, which is flip-chip mounted on the wiring substrate (interposer) 30, is placed in an opening of a holder 60. The holder 60 is arranged in a refrigerator in charge of cooling. The holder 60 may be made of, for example, a metal such as Al, etc., or high thermal conductivity ceramics.

A wiring pad and the ground plane 312 on the second wiring layer 32 of the wiring substrate (interposer) 30 are connected to a wiring and a ground plane on a first wiring layer 51 of the board 50 via probe pins 44, connected to a second wiring layer 52 via a through via 55 and connected to a connector(s) 54 from a wiring of the second wiring layer. The board is made of PCB (Printed Circuit Board). The probe pins 44 is accommodated in a housing 43 of a socket 40. The through via 55 penetrates a substrate 53. The through via 34 of the wiring substrate (interposer) 30 has through vias for ground and for signal. The probe pins 44 for ground and for signal are provided corresponding to the through vias for ground and for signal, respectively. Each of the probe pins 44 is illustrated as a both-ends movable pin with plungers on both sides axially movable (along longitudinal direction) by a biasing force of a coil spiring in a barrel. However, it may be a one-end movable pin with only a plunger of one side movable axially (longitudinal direction) by a biasing force of a coil spring in a barrel. Regarding the probe pins 44, a metal (alloy materials) with excellent conductivity, high hardness, and excellent processability may be used. The probe pins 44 may include a superconducting material which is the same as, or different from, the wiring layer 11 of the quantum chip 10. The probe pins 44 may preferably be made of a non-magnetic material. The probe pins 44 may preferably include any one selected from a group including a palladium (Pd) alloy, a gold alloy, beryllium copper (BeCu), gold (plated), niobium (Nb), niobium titanium (Nb-Ti), and titanium (Ti). The through via 55 is illustrated as a via (conformal via) in which a conductive layer is formed with a constant thickness along an inner wall of a via hole, but the through via 55 may be a filled via which is a via hole (closed via hole) filled with a conductive layer(s). The connector 54 corresponds to each connector of the signal terminal (connector), the pump terminal (connector), and the control terminal (connector) in FIG. 4A and FIG. 4B, and it includes a high-frequency coaxial connector as the IO terminal (connector) and the pump terminal (connector), and includes, for example, a connector for a twisted cable as a control terminal (connector). The substrate 53 of the board 50 may be a single layer or a substrate composed of a plurality of layers.

As other examples of a configuration other than FIG. 8A, for example, a configuration illustrated in FIG. 8B and FIG. 8C may be used. FIG. 8B is a schematic cross-sectional view illustrating an example of a configuration of the quantum chip 10 for external connection and FIG. 8C is a schematic perspective view thereof. FIG. 8B corresponds to a cross-sectional view of an A-A′ line in FIG. 8C. The quantum chip 10 faces the first wiring layer 31 of the wiring substrate (interposer) 30, which is placed on the holder 60 made of a conductive member and connected thereto with bumps 35. On the first wiring layer 31 of the wiring substrate (interposer) 30, wiring is routed to bonding pads 36 therearound (FIG. 8C). The second wiring layer 32 of the wiring substrate (interposer) 30 and the second wiring layer 52 of the board 50 are ground layers and are placed on the holder 60. The bonding pads 36 around the first wiring layer 31 of the wiring substrate (interposer) 30 is wire-bonded with bonding pads 56 (FIG. 8C) of the first wiring layer 51 of the board 50 by bonding wire 161. The bonding pads 56 of the board 50 are connected to connectors 54 by wirings on the first wiring layer 51.

In the bonding pads 36 around the first wiring layer 31 of the wiring substrate (interposer) 30, the bonding pads 56 of the first wiring layer 51 of the board 50, the connectors (coaxial connectors) 54, pads that connect to an inductive coupling port L and a capacitive coupling port C of a coupler (CPL) of the quantum chip 10 are to be LC and CC, respectively, and pads that connect to an inductive coupling port L and a capacitive coupling port C of a qubit (JPO) thereof are to be LJ and CJ, respectively. In FIG. 8C, each of the connectors 54 is illustrated as a multiport coaxial connector, for drawing convenience.

In the board 50, a plurality of bonding pads 56 that are arranged and connected by wiring to the plurality of ports of the connectors 54 at the bottom of the drawing, respectively, are labeled LC, CJ, LC, CJ, LC, CC, LJ, in order from left to right in the drawing. Regarding a plurality of wirings (lines) connecting to the inductive coupling ports L and the capacitive coupling ports C of the qubit (JPO) and the coupler (CPL) of the quantum chip 10, respectively, for example, a wiring (signal line) connected to the capacitive coupling port C of the quantum chip 10 and a wiring (pump line/control line) connected to the inductive coupling port L for the quantum chip 10 are arranged alternately.

Regarding the wirings (pump line/control line) connected to the plurality of bonding pads 36 in the first wiring layer 31 of the wiring substrate (interposer) 30, a wiring (signal line) connected to each of the capacitive coupling ports C of the qubit (JPO) and the coupler (CPL) with the bumps 35 and a wiring (pump lines/control lines) connected to each of the inductive coupling ports L thereof are arranged alternately, as well.

In FIG. 8C, wiring pattern of the first wiring layer 31 of the wiring substrate (interposer) 30 includes at least one of a first pattern and a second pattern.

The first pattern includes a pattern of adjacent three lines in which one of a second line (CJ) and a fourth lines (CC) is disposed between two lines selected from among first lines (LJs) and third lines (LCs) with duplication allowed such as both first lines, or both third lines.

The second pattern that includes a pattern of adjacent three lines in which two lines selected from among the second lines (CJs) and the fourth lines (CCs) with duplication allowed are disposed on both sides of one of the first lines (LJs) and the third lines (LCs).

Each of the first lines (pump lines) or pads (LJs) is connected to the inductive coupling port L of each qubit JPO of the quantum chip 10;
each of the second lines (signal lines) or pads (CJs) is connected to the capacitive coupling port C of each qubit JPO;

Each of the third lines (control lines) or pads (LCs) is connected to the inductive coupling port L of each coupler CPL; and
each of the fourth lines (signal lines) or pads (CCs) is connected to the capacitive coupling port C of each coupler CPL.

In FIG. 8C, regarding LC, CJ, LC, CJ, LC, CC, and LJ in an array of the bonding pads 36,
CJ is arranged between LC and LC;
CC is arranged between LC and LJ;
CJ and CJ are arranged on both sides of LC; and
CJ and CC are arranged on both sides of LC.
   In addition to the above, it includes combinations in which inductive coupling ports and the coupling ports of the coupler CPL and the qubit JPO are arranged alternately.

In the second wiring layer 52 of the board 50 in FIG. 8A, regarding wiring connecting the through via 55 to the connector 54, the wirings (signal lines) connected to the capacitive coupling ports C of the quantum chip 10 and the wirings (pump lines/control lines) connected to the inductive coupling ports L thereof may be, as a matter of course, arranged alternately.

According to the examples of the present disclosure, qubits and couplers are arranged on a two-dimensional planar square lattice (square lattice) to realize a two-dimensional arrangement of qubits in the close-packed structure. In addition, the three-dimensional wiring structure saves wiring space on the two-dimensional plane. Furthermore, regarding the lines connecting the inductive coupling ports L and the capacitive coupling ports C of the coupler (CPL) and the qubit (JPO), respectively, the effect of crosstalk between the lines (between terminals) can be reduced.

The above examples of the disclosure can partially or entirely be described as following Supplementary notes (Notes), though not limited thereto.

(Note 1) A quantum device including a quantum chip including a two-dimensional array of a plurality of couplers and a plurality of qubits, on a wiring layer thereof, wherein the two-dimensional array of the quantum chip includes: a first unit region including a first coupler, a first qubit, a second coupler, and a second qubit on first to fourth vertices thereof in this order; and a second unit region including the first coupler, the second qubit, a third coupler, and a third qubit on first to fourth vertices thereof in this order, the first and fourth vertices in the first unit region being the first and second vertices in the second unit region, respectively.

The first unit region includes, therewithin: a capacitive coupling port of the second coupler disposed in a vicinity thereof; and an inductive coupling port of the second qubit disposed in a vicinity thereof, the second qubit being arranged adjacent to the second coupler.

The second unit region includes, therewithin: a capacitive coupling port of the second qubit disposed in a vicinity in a vicinity thereof; and an inductive coupling port of the third coupler disposed in a vicinity in a vicinity thereof, the third coupler being arranged adjacent to the second qubit.

### (Note 2)

In the quantum chip of the quantum device according to Note 1, the two-dimensional array of the quantum chip includes: a third unit region including the first coupler, the third qubit, a fourth coupler, and a fourth qubit on first to fourth vertices thereof in this order, and a fourth unit region including the first coupler, the fourth qubit, a fifth coupler and the first qubit on first to fourth vertices thereof in this order, wherein the first vertex of the first unit region, the fourth vertex of the second unit region and the second vertex of the first unit region are the first, second and fourth vertices of the third unit region, respectively, and
the first vertex in the first unit region and the fourth vertex in the third unit region are the first and second vertices in the fourth unit region, respectively,

The third unit region includes, therewithin: an inductive coupling port of the third qubit disposed in a vicinity thereof; and a capacitive coupling port of the first coupler disposed in a vicinity thereof, the first coupler being arranged adjacent to the third qubit.

The fourth unit region includes, therewithin: a capacitive coupling port of the first qubit disposed in a vicinity thereof; and an inductive coupling port of the first coupler disposed in a vicinity thereof, the first coupler being arranged adjacent to the first qubit.

(Note 3) The quantum device according to Note 2, includes a wiring substrate with a first surface arranged facing the wiring layer of the quantum chip, wherein the inductive coupling port and the capacitive coupling port of each of the first to fourth qubits and the inductive coupling port and the capacitive coupling port of each of the first to fifth couplers provided on the wiring layer of the quantum chip, are connected respectively via corresponding bumps to the first surface of the wiring substrate and via wirings of the wiring substrate further connected to corresponding terminals for external connection of the wiring substrate, respectively.
(Note 4) In the quantum device according to Note 3, the bumps include at least a ground bump having a first end connected to a ground plane surrounding at least one of the first to fourth qubits, on the wiring layer of the quantum chip, and a second end connected to a ground of the first surface of the wiring substrate.
(Note 5) In the quantum device according to Note 2, each of the first to fourth qubits includes a first arm electrode and a second arm electrode extending in opposite directions from a center thereof and disposed respectively in mutually adjacent unit regions.

The quantum device includes: the inductive coupling port for each of the qubits opposing a one side edge in a longitudinal direction of the first arm electrode, and the capacitive coupling port of each of the qubits opposing one side edge in a longitudinal direction of the second arm electrode.

(Note 6) In the quantum device according to Note 5, each of the first to fourth qubits includes a superconducting quantum interference device (SQUID) including at least two Josephson junctions in a loop, between an edge of one side in the longitudinal direction of the first arm electrode and the ground.

The inductive coupling port for each of the qubits includes a first end portion of a first line opposing the superconducting quantum interference device, the first line having the first end elongated to a vicinity of the superconducting quantum interference device and connected to a ground, and a second end connected to a current control part.

The capacitive coupling port includes a first end of a second line, the second line having the first end opposed to one side edge in longitudinal direction of the second arm electrode, and a second end connected to a signal source.

(Note 7) In the quantum device described in any one of Notes 2 to 6,each of the first to fifth couplers includes a first electrode and a second electrode which are spaced apart and opposed each other, wherein the first electrode includes first and second opposing portions capacitively coupled to two of four nearest-neighbor qubits to the coupler, respectively, and wherein the second electrode includes third and fourth opposing portions capacitively coupled to remaining two of the four nearest-neighbor qubits to the coupler, respectively.

Each of the first to fifth couplers includes a superconducting quantum interference device (SQUID) including at least two Josephson junctions in a loop and connecting between the first electrode and the second electrode, wherein the inductive coupling port for each of the couplers includes a first end of a third line, the third line having the first end extended to a vicinity of the superconducting quantum interference device and connected to a ground, and a second end connected to a current control part, and wherein the capacitive coupling port of each of the couplers includes a first end of a fourth line, the fourth line having the first end arranged at one end opposing one side edge of the first or second electrode, and a second end connected to a signal source.

(Note 8) In the quantum device according to Note 3, the wiring substrate includes: a wiring connecting via a corresponding bump to the capacitive coupling port of each qubit of the quantum chip; a wiring connecting via a corresponding bump to the inductive coupling port of the each qubit of the quantum chip, a wiring connecting via a corresponding bump to the inductive coupling port of each coupler of the quantum chip; and a wiring connecting via a corresponding bump to the capacitive coupling port of the each coupler of the quantum chip, wherein the wiring substrate includes a wiring pattern in which the wiring connecting to the capacitive coupling port and the wiring connecting to the inductive coupling port are arranged alternately.
(Note 9) In the quantum device according to Note 3, the wiring substrate includes: a plurality of first wirings, each connecting via a corresponding bump to the capacitive coupling port of each qubit of the quantum chip; a plurality of second wirings, each connecting via a corresponding bump to the inductive coupling port of the each qubit of the quantum chip, a plurality of third wirings, each connecting via a corresponding bump to the inductive coupling port of each coupler of the quantum chip; and a plurality of fourth wirings, each connecting via a corresponding bump to the capacitive coupling port of the each coupler of the quantum chip.

The wiring substrate includes a first wiring pattern and/or a second wiring pattern with respect to the first to four lines.

The first wiring pattern includes a pattern of adjacent three lines in which one of the second and fourth lines is disposed between two lines selected from among the first and the third lines, wherein as the two lines, the two first lines, two third lines, or the first and third lines are selectable.

The second wiring pattern includes a pattern of adjacent three lines in which two lines selected from among the second lines and the fourth lines, are disposed on both sides of one of the first lines and the third lines, wherein as the two lines, the two second lines, two fourth lines, or the second and the fourth lines are selectable.

(Note 10) The quantum device according to Note 3, or 8, further includes a PCB (Printed Circuit Board) connected to the wiring substrate.

The PCB includes a plurality of connectors for external connection.

The plurality of connectors connected via wiring to the terminals for external connection of the wiring substrate which are connected via the bumps to the capacitive coupling port of each of the qubit and the coupler of the quantum chip and the inductive coupling port of each of the qubit and the coupler of the quantum chip.

(Note 11) In the quantum device described in Note 10, the PCB includes a plurality of first wirings, each connecting via the wiring substrate to the capacitive coupling port of each qubit of the quantum chip; a plurality of second wirings, each connecting via the wiring substrate to the inductive coupling port of the each qubit of the quantum chip, a plurality of third wirings, each connecting via the wiring substrate to the inductive coupling port of each coupler of the quantum chip; and a plurality of fourth wirings, each connecting via the wiring substrate to the capacitive coupling port of the each coupler of the quantum chip.

The wiring substrate includes a first wiring pattern and/or a second wiring pattern with respect to the first to four lines.

The first wiring pattern includes a pattern of adjacent three lines in which one of the second and fourth lines is disposed between two lines selected from among the first and the third lines, wherein as the two lines, the two first lines, two third lines, or the first and third lines are selectable.

The second wiring pattern includes a pattern of adjacent three lines in which two lines selected from among the second lines and the fourth lines, are disposed on both sides of one of the first lines and the third lines, wherein as the two lines, the two second lines, two fourth lines, or the second and the fourth lines are selectable.

(Note 12) In the quantum device described in any one of Notes 2 to 11, the first coupler couples the first to fourth qubits by a four-body interaction.
(Note 13) In the quantum device described in any one of Notes 2 to 12, in the quantum chip, at least one qubit among the four qubits included one unit structure configured with the coupler and four nearest-neighbor qubits to the coupler, is shared by one or a plurality of unit structures other than the one unit structure to compose a quantum annealing machine

Each disclosure of NPL 1 is incorporated herein by reference thereto. Variations and adjustments of the examples are possible within the scope of the overall disclosure (including the claims) based on the basic technical concept. Various combinations and selections of examples and disclosed elements (including the elements in each of the claims, examples, drawings, etc.) are possible within the scope of the claims of the present application. That is, the present disclosure includes various variations and modifications that could be made by those skilled in the art according to the overall disclosure including the claims and the technical concept.

What is claimed is:

1. A quantum device comprising:
a quantum chip including a two-dimensional array of a plurality of couplers and a plurality of qubits, on a wiring layer thereof,
wherein the two-dimensional array of the quantum chip includes:
a first unit region including a first coupler, a first qubit, a second coupler, and a second qubit on first to fourth vertices thereof in this order; and
a second unit region including the first coupler, the second qubit, a third coupler, and a third qubit on first to fourth vertices thereof in this order, the first and fourth vertices in the first unit region being the first and second vertices in the second unit region, respectively,
wherein the first unit region includes, therewithin:
a capacitive coupling port of the second coupler disposed in a vicinity thereof; and
an inductive coupling port of the second qubit disposed in a vicinity thereof, the second qubit being arranged adjacent to the second coupler, and
wherein the second unit region includes, therewithin:
a capacitive coupling port of the second qubit disposed in a vicinity in a vicinity thereof; and
an inductive coupling port of the third coupler disposed in a vicinity in a vicinity thereof, the third coupler being arranged adjacent to the second qubit.

2. The quantum device according to claim 1, wherein the two-dimensional array of the quantum chip includes:
a third unit region including the first coupler, the third qubit, a fourth coupler, and a fourth qubit on first to fourth vertices thereof in this order, and
a fourth unit region including the first coupler, the fourth qubit, a fifth coupler and the first qubit on first to fourth vertices thereof in this order,
wherein the first vertex of the first unit region, the fourth vertex of the second unit region and the second vertex of the first unit region are the first, second and fourth vertices of the third unit region, respectively, and
the first vertex in the first unit region and the fourth vertex in the third unit region are the first and second vertices in the fourth unit region, respectively,
wherein the third unit region includes, therewithin:
an inductive coupling port of the third qubit disposed in a vicinity thereof; and
a capacitive coupling port of the first coupler disposed in a vicinity thereof, the first coupler being arranged adjacent to the third qubit, and
wherein the fourth unit region includes, therewithin:
a capacitive coupling port of the first qubit disposed in a vicinity thereof; and
an inductive coupling port of the first coupler disposed in a vicinity thereof, the first coupler being arranged adjacent to the first qubit.

3. The quantum device according to claim 2, further comprising
a wiring substrate with a first surface arranged facing the wiring layer of the quantum chip,
wherein the inductive coupling port and the capacitive coupling port of each of the first to fourth qubits and the inductive coupling port and the capacitive coupling port of each of the first to fifth couplers provided on the wiring layer of the quantum chip, are connected respectively via corresponding bumps to the first surface of the wiring substrate and via wirings of the wiring substrate further connected to corresponding terminals for external connection of the wiring substrate, respectively.

4. The quantum device according to claim 3, wherein the bumps include at least a ground bump having a first end connected to a ground plane surrounding at least one of the first to fourth qubits, on the wiring layer of the quantum chip, and a second end connected to a ground of the first surface of the wiring substrate.

5. The quantum device according to claim 2, wherein each of the first to fourth qubits includes a first arm electrode and a second arm electrode extending in opposite directions from a center thereof and disposed respectively in mutually adjacent unit regions, and
wherein the quantum device includes:
the inductive coupling port for each of the qubits opposing a one side edge in a longitudinal direction of the first arm electrode, and
the capacitive coupling port of each of the qubits opposing one side edge in a longitudinal direction of the second arm electrode.

6. The quantum device according to claim 5, wherein each of the first to fourth qubits includes
a superconducting quantum interference device (SQUID) including at least two Josephson junctions in a loop, between an edge of one side in the longitudinal direction of the first arm electrode and the ground,
wherein the inductive coupling port for each of the qubits includes a first end portion of a first line opposing the superconducting quantum interference device, the first line having the first end elongated to a vicinity of the superconducting quantum interference device and connected to a ground, and a second end connected to a current control part, and
wherein the capacitive coupling port includes a first end of a second line, the second line having the first end opposed to one side edge in longitudinal direction of the second arm electrode, and a second end connected to a signal source.

7. The quantum device according to claim 2, wherein each of the first to fifth couplers includes a first electrode and a second electrode which are spaced apart and opposed each other,
wherein the first electrode includes first and second opposing portions capacitively coupled to two of four nearest-neighbor qubits to the coupler, respectively,
wherein the second electrode includes third and fourth opposing portions capacitively coupled to remaining two of the four nearest-neighbor qubits to the coupler, respectively,
wherein each of the first to fifth couplers includes a superconducting quantum interference device (SQUID) including at least two Josephson junctions in a loop and connecting between the first electrode and the second electrode,
wherein the inductive coupling port for each of the couplers includes a first end of a third line, the third line having the first end extended to a vicinity of the superconducting quantum interference device and connected to a ground, and a second end connected to a current control part, and
wherein the capacitive coupling port of each of the couplers includes a first end of a fourth line, the fourth line having the first end arranged at one end opposing one side edge of the first or second electrode, and a second end connected to a signal source.

8. The quantum device according to claim 3, wherein the wiring substrate includes:
a wiring connecting via a corresponding bump to the capacitive coupling port of each qubit of the quantum chip;
a wiring connecting via a corresponding bump to the inductive coupling port of the each qubit of the quantum chip,
a wiring connecting via a corresponding bump to the inductive coupling port of each coupler of the quantum chip; and
a wiring connecting via a corresponding bump to the capacitive coupling port of the each coupler of the quantum chip,
wherein the wiring substrate includes a wiring pattern in which the wiring connecting to the capacitive coupling port and the wiring connecting to the inductive coupling port are arranged alternately.

9. The quantum device according to claim 3, wherein the wiring substrate includes
a plurality of first wirings, each connecting via a corresponding bump to the capacitive coupling port of each qubit of the quantum chip;
a plurality of second wirings, each connecting via a corresponding bump to the inductive coupling port of the each qubit of the quantum chip,
a plurality of third wirings, each connecting via a corresponding bump to the inductive coupling port of each coupler of the quantum chip; and
a plurality of fourth wirings, each connecting via a corresponding bump to the capacitive coupling port of the each coupler of the quantum chip,
wherein the wiring substrate includes a first wiring pattern and/or a second wiring pattern with respect to the first to four lines,
the first wiring pattern including a pattern of adjacent three lines in which one of the second and fourth lines is disposed between two lines selected from among the first and the third lines, wherein as the two lines, the two first lines, two third lines, or the first and third lines are selectable,
the second wiring pattern including a pattern of adjacent three lines in which two lines selected from among the second lines and the fourth lines, are disposed on both sides of one of the first lines and the third lines, wherein as the two lines, the two second lines, two fourth lines, or the second and the fourth lines are selectable.

10. The quantum device according to claim 3, further comprising
a PCB (Printed Circuit Board) connected to the wiring substrate, wherein the PCB includes a plurality of connectors for external connection,
the plurality of connectors connected via wiring to the terminals for external connection of the wiring substrate which are connected via the bumps to the capacitive coupling port of each of the qubit and the coupler of the quantum chip and the inductive coupling port of each of the qubit and the coupler of the quantum chip.

11. The quantum device according to claim 10, wherein the PCB includes
a plurality of first wirings, each connecting via the wiring substrate to the capacitive coupling port of each qubit of the quantum chip;
a plurality of second wirings, each connecting via the wiring substrate to the inductive coupling port of the each qubit of the quantum chip,
a plurality of third wirings, each connecting via the wiring substrate to the inductive coupling port of each coupler of the quantum chip; and
a plurality of fourth wirings, each connecting via the wiring substrate to the capacitive coupling port of the each coupler of the quantum chip,
wherein the wiring substrate includes a first wiring pattern and/or a second wiring pattern with respect to the first to four lines,
the first wiring pattern including a pattern of adjacent three lines in which one of the second and fourth lines is disposed between two lines selected from among the first and the third lines, wherein as the two lines, the two first lines, two third lines, or the first and third lines are selectable,
the second wiring pattern including a pattern of adjacent three lines in which two lines selected from among the second lines and the fourth lines, are disposed on both sides of one of the first lines and the third lines, wherein as the two lines, the two second lines, two fourth lines, or the second and the fourth lines are selectable.

12. The quantum device according to claim 2, wherein in the quantum chip, the first coupler couples the first to fourth qubits by a four-body interaction.

13. The quantum device according to claim 2, wherein in the quantum chip, at least one qubit among the four qubits included one unit structure configured with the coupler and four nearest-neighbor qubits to the coupler, is shared by one or a plurality of unit structures other than the one unit structure to compose a quantum annealing machine.
